(19) United States
(12) Patent Application Publication
(10) Pub. No.: US 2026/0026201 A1
(43) Pub. Date: Jan. 22, 2026

(54) DISPLAY DEVICE

(71) Applicant: Samsung Display Co., Ltd., Yongin-si (KR)

(72) Inventor: Eun-Ah KIM, Yongin-si (KR)

(21) Appl. No.: 19/232,573

(22) Filed: Jun. 9, 2025

(30) Foreign Application Priority Data
Jul. 19, 2024 (KR) 10-2024-0095544

(51) Int. Cl. H10K 59/122; H10K 59/35; H10K 59/80

(52) U.S. Cl. CPC H10K 59/122; H10K 59/873; H10K 59/353

(57) ABSTRACT

A display device includes: a display panel including: a display unit; and an encapsulation layer on the display unit, wherein the display panel includes a folding area and a non-folding area, the display unit including: a substrate; a transistor on the substrate; a first electrode on the transistor; a partition wall on the first electrode and including an opening defining a light emitting area and a non-light emitting area; and a light emitting layer within the opening, the encapsulation layer including: a first inorganic layer; a second inorganic layer on the first inorganic layer; and an organic layer between the first inorganic layer and the second inorganic layer, and the first inorganic layer includes a first pattern portion in the non-light emitting area overlapping the folding area.

### CROSS-REFERENCE TO RELATED APPLICATION

The present application claims priority to and the benefit of Korean Patent Application No. 10-2024-0095544, filed on Jul. 19, 2024, in the Korean Intellectual Property Office, the entire contents of which are incorporated herein by reference.

### BACKGROUND

### 1. Field

Aspects of some embodiments of the present disclosure relate to a display device.

### 2. Description of the Related Art

A display device such as an organic light emitting diode display and a liquid crystal display device includes a display panel manufactured by forming a plurality of layers and elements on a substrate. Recently, a flexible display panel and a display device including the same have been developed.

The display device may be classified into a bendable display device, a foldable display device, a rollable display device, a stretchable display device, and the like depending on its usage and form. Among them, the foldable display device may be folded and unfolded like a book.

The foldable display device may be capable of being folded and compactly carried, and when used, it may be unfolded to allow enjoyment of a wide screen.

The above information disclosed in this Background section is only for enhancement of understanding of the background and therefore the information discussed in this Background section does not necessarily constitute prior art.

### SUMMARY

Aspects of some embodiments of the present disclosure may include a display device that is robust against folding stress by patterning an inorganic layer among encapsulation layers of a display panel used in a foldable display device.

Aspects of some embodiments of the present disclosure include a display device including: a display panel including: a display unit; and an encapsulation layer on the display unit, wherein the display panel includes a folding area and a non-folding area, the display unit includes: a substrate; a transistor on the substrate; a first electrode on the transistor; a partition wall on the first electrode and including an opening defining a light emitting area and a non-light emitting area; and a light emitting layer within the opening, the encapsulation layer comprising: a first inorganic layer; a second inorganic layer on the first inorganic layer; and an organic layer between the first inorganic layer and the second inorganic layer, and the first inorganic layer includes a first pattern portion in the non-light emitting area overlapping the folding area.

According to some embodiments, a material that is identical to a material of the organic layer may be on the first pattern portion.

According to some embodiments, a first material having a lower modulus than that of the first inorganic layer may be on the first pattern portion.

According to some embodiments, the first material may include at least one of an organic material or an inorganic material.

According to some embodiments, the first material may include a styrene-based thermoplastic elastomer.

According to some embodiments, the first pattern portion may be a region from which at least a portion of the first inorganic layer has been removed.

According to some embodiments, the second inorganic layer may further comprise a second pattern portion in the non-light emitting area overlapping the folding area.

According to some embodiments, the second pattern portion may be a region from which at least a portion of the second inorganic layer has been removed.

According to some embodiments, the first pattern portion and the second pattern portion may overlap each other.

According to some embodiments, the first pattern portion and the second pattern portion may be spaced apart from each other.

According to some embodiments, the display unit may have a first unit structure that comprises a red pixel, a green pixel, and a blue pixel, and the first unit structure is arranged repeatedly.

According to some embodiments, the first pattern portion may surround the first unit structure.

According to some embodiments, the red pixel and the blue pixel may be at corners of a virtual quadrangle with the green pixel as a center point, the red pixel may be at an opposite corner with the green pixel therebetween, and the blue pixel may be at an opposite corner of the red pixel in a first direction, with the green pixel therebetween.

Aspects of some embodiments of the present disclosure include a display device including: a display panel including: a display unit; and an encapsulation layer on the display unit, wherein the display panel includes a folding area and a non-folding area, the display unit includes: a substrate; a transistor on the substrate; a first electrode on the transistor; a partition wall on the first electrode and including an opening defining a light emitting area and a non-light emitting area; a light emitting layer within the opening; and a second electrode on the light emitting layer, and the encapsulation layer comprising: a first organic layer on the second electrode; a second inorganic layer on the first inorganic layer; and an organic layer between the first inorganic layer and the second inorganic layer, and at least one of the first inorganic layer or the second inorganic layer includes a recess portion in the non-light emitting area that overlaps the folding area.

According to some embodiments, a material that is identical to a material of the organic layer may be in the recess portion.

According to some embodiments, a first material having a lower modulus than that of the first inorganic layer may be in the recess portion.

According to some embodiments, the first material may include at least one of an organic material or an inorganic material.

According to some embodiments, the first material may include a styrene- based thermoplastic elastomer.

According to some embodiments, the recess portion may be an area where the first inorganic layer and the second inorganic layer have been at least partially removed.

According to some embodiments, the recess portion in the first inorganic layer and the recess portion in the second inorganic layer may overlap each other.

According to some embodiments, the recess portion in the first inorganic layer and the recess portion in the second inorganic layer may be spaced apart from each other.

Aspects of some embodiments of the present disclosure includes an electronic device including: a memory; a processor executing an application stored in the memory; and a display device comprising a display module outputting video information provided by the application, wherein the display device includes: a display panel comprising: a display unit; and an encapsulation layer on the display unit, wherein the display panel includes a folding area and a non-folding area, the display unit comprising: a substrate; a transistor on the substrate; a first electrode on the transistor; a partition wall on the first electrode and including an opening defining a light emitting area and a non-light emitting area; and a light emitting layer within the opening, the encapsulation layer comprising: a first inorganic layer; a second inorganic layer on the first inorganic layer; and an organic layer between the first inorganic layer and the second inorganic layer, and the first inorganic layer includes a first pattern portion in the non-light emitting area overlapping the folding area.

According to some embodiments, a material that is identical to a material of the organic layer is on the first pattern portion.

According to some embodiments of the present disclosure, the inorganic layer of the encapsulating layer overlapping the folding area may be patterned, so a material other than the inorganic layer may be in the patterned area, thereby providing a display panel that is relatively robust to folding stress.

### BRIEF DESCRIPTION OF THE DRAWINGS

FIG. 1 illustrates a schematic perspective view of a display device according to some embodiments.

FIG. 2 illustrates a schematic top plan view of a display panel according to some embodiments.

FIG. 3 illustrates a cross-sectional view showing a display device according to some embodiments, taken along the line A1-A2 of the display device illustrated in FIG. 1.

FIG. 4 illustrates a cross-sectional view showing a display device according to some embodiments.

FIG. 5 and FIG. 6 each illustrate a cross-sectional view of a display panel according to some embodiments.

FIG. 7 illustrates a cross-sectional view showing a display device according to some embodiments.

FIG. 8 illustrates a schematic cross-sectional view of a display panel according to some embodiments.

FIG. 9 to FIG. 11 illustrate cross-sectional views showing a pixel layout and a pattern portion of a first inorganic layer according to some embodiments.

FIG. 12 illustrates a cross-sectional view showing a display device according to some embodiments.

FIG. 13 to FIG. 17 each illustrate a cross-sectional view of a display panel according to some embodiments.

FIG. 18 illustrates a block diagram of an electronic device according to some embodiments.

FIG. 19 illustrates schematic diagrams of electronic devices according to some embodiments.

### DETAILED DESCRIPTION

Aspects of some embodiments of the present disclosure will be described more fully hereinafter with reference to the accompanying drawings, in which embodiments of the disclosure are shown. As those skilled in the art would realize, the described embodiments may be modified in various different ways, all without departing from the spirit or scope of embodiments according to the present disclosure.

To clearly describe the present disclosure, parts that are irrelevant to the description, or not necessary to enable a person having ordinary skill in the art to make or use embodiments according to the present disclosure, may be omitted, and like numerals refer to like or similar components throughout the specification.

Further, because sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It should be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means located on or below the object portion, and does not necessarily mean located on the upper side of the object portion based on a gravitational direction.

In addition, unless explicitly described to the contrary, the word “comprise” and variations such as “comprises” and “comprising” should be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, in the specification, “connected” means that two or more components are not only directly connected, but two or more components may be connected indirectly through other components, physically connected as well as being electrically connected, or it may be referred to by different names depending on the location or function, but may include connecting parts that are substantially integral to each other.

In addition, throughout the specification, when it is said that a portion of a wire, layer, film, region, plate, component, etc., “extends in a first direction or a second direction,” this does not indicate only a straight shape extending straight in the corresponding direction, but also indicates a structure that generally extends along the first direction or the second direction, and it includes a structure that is bent in a portion, has a zigzag structure, or extends while including a curved structure.

In addition, an electronic device (e.g., a mobile phone, TV, monitor, notebook computer, etc.) including a display device, a display panel, etc. described in the specification, or an electronic device including a display device and a display panel manufactured by the manufacturing method described in the specification, are not excluded from the scope of the present specification.

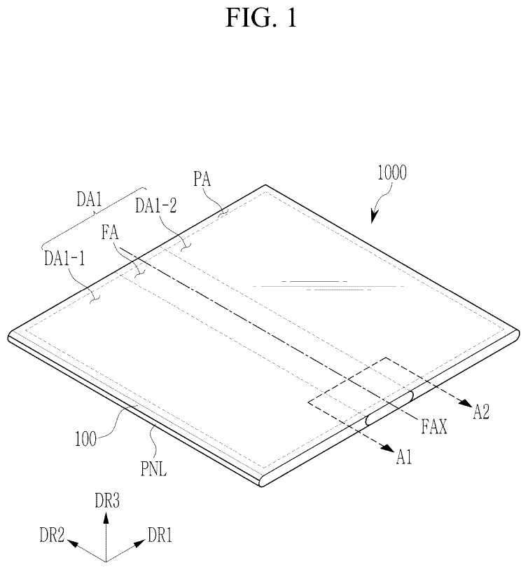

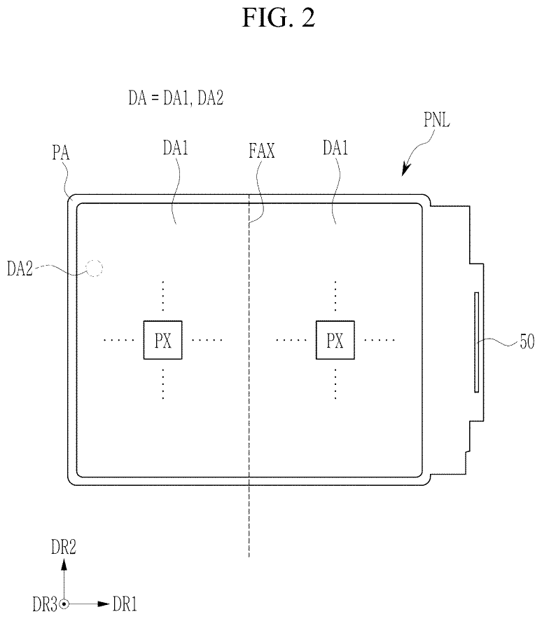

A display device according to some embodiments will be described in more detail with reference to FIG. 1 and FIG. 2. FIG. 1 illustrates a schematic perspective view of a display device according to some embodiments. FIG. 2 illustrates a schematic top plan view of a display panel according to some embodiments.

Referring to FIG. 1, the display device 1000 according to some embodiments may be a flexible display device and may be a device for displaying moving images or still images, which may be used as a display screen of various products, such as televisions, laptop computers, monitors, billboards, the Internet of Things (IOT), etc., as well as portable electronic devices such as mobile phones, smartphones, tablet personal computers, mobile communication terminals, electronic notebooks, e-books, portable multimedia players (PMP), navigation systems, and ultra-mobile PCs (UMPC). In addition, the display device 1000 according to some embodiments may be used in a wearable device such as a smart watch, a watch phone, a glasses display, or a head mounted display (HMD). In addition, the display device 1000 according to some embodiments may be used as an instrument panel of a vehicle, a center information display (CID) provided at a center fascia or dashboard of a vehicle, a room mirror display that replaces a side mirror of a vehicle, or a display provided on a back surface of a front seat of a vehicle.

The display device 1000 may display images in a third direction DR3 on a display surface parallel to each of a first direction DR1 and a second direction DR2. A display surface on which images are displayed may correspond to a front surface of the display device 1000, and the images may include a still image (e.g. static images) as well as a dynamic image (e.g., video images).

The display device 1000 according to some embodiments may sense a user input applied from the outside. The user input may include various types of external inputs, such as a part of a user's body, light, heat, or pressure. According to some embodiments, the user input may be input by a user's hand applied that is recognized on the front, or input from a pen such as a stylus used by the user, but the present disclosure is not limited thereto. In addition, the display device 1000 may sense the user input applied to the side surface or the rear surface of the display device 1000 depending on a structure of the display device 1000.

The display device 1000 may be a foldable, flexible display device. The display device 1000 may be folded outwardly or inwardly based on, or about, a folding axis FAX, without damaging the display device 1000. When folded outward based on the folding axis FAX, display surfaces of the display device 1000 are located outside in the third direction DR3 to display images in opposite directions. When folded inward based on the folding axis FAX, the display surfaces may not be visually recognized from the outside (e.g, by users).

According to some embodiments, the display device 1000 may include a display area DA1 and a peripheral area PA (hereinafter also referred to as a non-display area). The display area DA1 is an area at which images are displayed, and may be an area in which an external input is sensed at the same time. The display area DA1 may be an area in which a plurality of pixels, to be described in more detail later, are arranged.

The display area DA1 may be divided into a first-1 display area DA1-1, a first-2 display area DA1-2, and a folding area FA. The first-1 display area DA1-1 and the first-2 display area DA1-2 may be located at left and right sides, respectively, with respect to (or at a center of) the folding axis FAX, and the folding area FA may be located between the first-1 display area DA1-1 and the first-2 display area DA1-2. In this case, when folded outward based on the folding axis FAX, the first-1 display area DA1-1 and the first-2 display area DA1-2 may be located on both sides in the third direction DR3, and images may be displayed in both directions. In addition, when folded inward based on the folding axis FAX, the first-1 display area DA1-1 and the first-2 display area DA1-2 may not be viewed from the outside.

FIG. 2 illustrates a planar structure of a display panel PNL that may be included in the display device according to some embodiments.

The display panel PNL may also have a display area DA located on a front surface, and the display area DA may be largely divided into a first display area DA1 (hereinafter also referred to as a main display area) and a second display area DA2 (hereinafter also referred to as a component area). The display area DA may include the first display area DA1 and the second display area DA2.

In the display area DA1, a plurality of light emitting diodes and a plurality of pixel circuit units for generating and transmitting a light emitting current to each of the light emitting diodes may be formed. One light emitting diode and one pixel circuit are called a pixel PX, wherein each pixel PX may include at least one light emitting diode and at least one pixel circuit unit.

The second display area DA2 may include a light transmitting area, and may additionally include a pixel for displaying an image. The second display area DA2 may be an area that at least partially overlaps an optical element such as a camera or an optical sensor. In FIG. 2, the second display area DA2 is shown as a circular shape at a left side of the display device, but the embodiments according to the present disclosure are not limited thereto. The second display area DA2 may comprise various numbers and shapes depending on a number and shape of optical elements.

The display device may receive an external signal required for an optical device through the second display area DA2, or may provide a signal output from the optical device to the outside. According to some embodiments, because the second display area DA2 overlaps the light transmitting area, an area of the peripheral area PA for forming the light transmitting area may be relatively reduced.

According to some embodiments, a boundary area may be located between the first display area DA1 and the second display area DA2.

The peripheral area PA may be further located outside the display area DA. In the embodiments of FIG. 2, the second display area DA2 is surrounded by the first display area DA1 so that an area of the display area DA is not reduced due to the second display area DA2, and the area of the peripheral area PA may not increase.

In FIG. 2, the peripheral area PA is also illustrated outside the display area DA, and a driver 50 is also illustrated in the peripheral area PA. The peripheral area PA may be divided into the driver 50, a connection line, and a bending area because the display area DA is located outside. According to some embodiments, a portion of the display panel DP where the driver 50 is located may be folded to the rear to position the driver 50 behind the display area DA, so that the display device may be completed.

In the embodiments of FIG. 2, the driver 50 is illustrated as being located in the peripheral area PA in the first direction DR1 of the display area DA, and although the driver 50 extends in a direction that is parallel to the folding axis FAX, a position of the driver 50 may be variously changed.

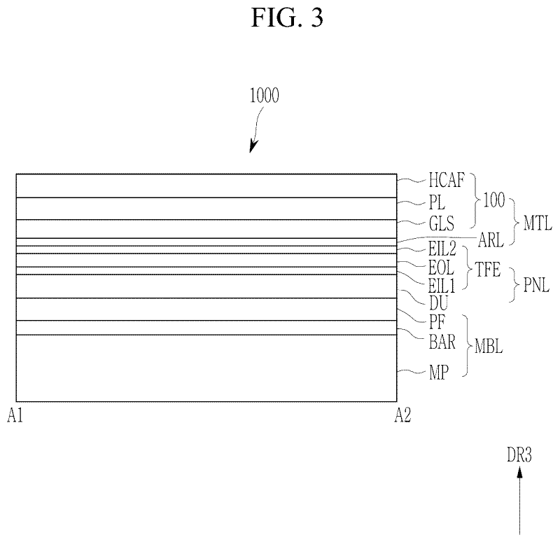

Hereinafter, an overall cross-sectional structure of a display device according to some embodiments will be described with reference to FIG. 3 together with FIG. 1 and FIG. 2 described above. FIG. 3 illustrates a cross-sectional view showing a display device according to some embodiments, taken along the line A1-A2 of the display device illustrated in FIG. 1.

Referring to FIG. 3, a display device 1000 according to some embodiments may include a lower module layer MBL located on a back surface of a display panel PNL and an upper module layer MTL located on a front surface thereof.

The lower module layer MBL may include a protective film PF, a barrier layer BAR, and a metal plate MP. The display panel PNL and the protective film PF, the protective film PF and the barrier layer BAR, and the barrier layer BAR and the metal plate MP may be attached to each other by an adhesive layer.

The adhesive layer may include an optically clear adhesive OCA, an optically clear resin OCR, or a pressure-sensitive adhesive PSA. More specifically, the adhesive layer may include a polymer resin such as an acrylic material, a silicone material, rubber, polyurethane, vinyl acetate, an epoxy resin, or styrene-butadiene-styrene (SBS).

The display panel PNL may include a display unit DU on which a plurality of pixels are located to display an image, an encapsulation layer TFE located at an upper portion of the display unit, and a touch sensor located on the encapsulation layer TFE to detect an external input. As shown in FIG. 1, the display panel PNL may include a front surface including the display area DA and the peripheral area PA. The display area DA may be an area in which a pixel is actuated by an electrical signal to emit light.

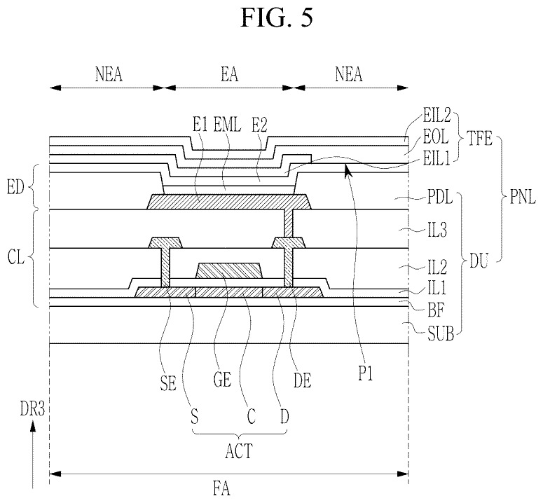

The encapsulating layer TFE may be located on the display unit DU. For example, the display unit DU may be sealed with the encapsulating layer TFE. In some embodiments, an encapsulation substrate formed of a glass material may be provided instead of the encapsulation layer TFE. The encapsulation layer may be located on the display unit DU, and the display unit DU may be provided between the substrate SUB (FIG. 5) and the encapsulation layer TFE. There may be a gap between the encapsulation substrate and the display unit DU, which may be filled with a filler material.

A touch sensor layer may be located on the encapsulation layer. A plurality of pixels are located at a lower portion of the touch sensor in the display panel PNL to display an image in the third direction DR3, and the touch sensor is located above the pixels in the third direction DR3 to sense an external input.

The protective film PF located on a back surface of the display panel PNL is a layer capable of strengthening impact resistance applied to the display panel PNL, and may also be called an impact-resistant layer. The protective film PF may be formed of polyimide (PI) or polyurethane, or may be formed of a mixed resin containing polyimide (PI) or polyurethane. Meanwhile, according to some embodiments, the protective layer PF may include a copolymer with at least one resin including a urethane functional group. Furthermore, the protective film PFL may be formed from polyteraphthalate.

The barrier layer BAR may be located on a back surface of the protective film PF, which can play a role in alleviating impact applied from the back surface of the display panel PNL. According to some embodiments, the barrier layer BAR may be formed in black to prevent or reduce light from a back surface thereof from being provided to the display panel DP, and may also serve to prevent or reduce the light provided from the display panel DP to the rear surface from being reflected and provided to the front surface. The barrier layer BAR may include polyimide PI.

The metal plate MP may be located on a back surface of the barrier layer BAR. The metal plate MP may enable the display device 1000 to remain in a folded state when the display device 1000 is folded based on the folding axis FAX. The metal plate MP may include a thin metal plate.

The upper module layer MTL may include an anti-reflection layer ARL and a cover window 100. The cover window 100 may include a glass layer GLS and a protective layer PL. The cover window WU may further include a light shielding layer.

The anti-reflection layer ARL and the glass layer GLS, and the glass layer GLS and the protective layer PL may be attached to each other by an adhesive layer.

The anti-reflection layer ARL may be located between the cover window 100 and the display panel PNL. The anti-reflection layer ARL may relatively reduce an amount of light incident from the outside onto the display panel PNL and reflected by the display panel PNL. The anti-reflection layer ARL may include a polarization layer. The anti-reflection layer ARL may include a combination of a color filter and a light shading member instead of a polarizing layer. According to some embodiments, the anti-reflection layer ARL may be omitted.

A glass layer GLS may be located on a front surface of the anti-reflection layer ARL. The glass layer GLS may include glass. The glass included in the glass layer GLS may be a silicate glass. The glass layer GLS may be, but is not limited to, a glass film UTG formed generally thin or locally thin.

A protective layer PL may be located on a front surface of the glass layer GLS. The protective layer PL may be intended to protect the glass layer GLS. The protective layer PL may include at least one of polymer resins such as polyethylene terephthalate (PET), poly(butylene terephthalate) (PBT), polycarbonate (PC), polyethylene naphthalate (PEN), polystyrene (PS), polymethylmethacrylate (PMMA), polyvinylchloride (PVC), polyethersulfone (PES), polypropylene (PP), or polyamide (PA).

The cover window 100 of the display device 1000 according to some embodiments may further include a hard coating layer (HCAF) located on a front surface of the protective layer PL.

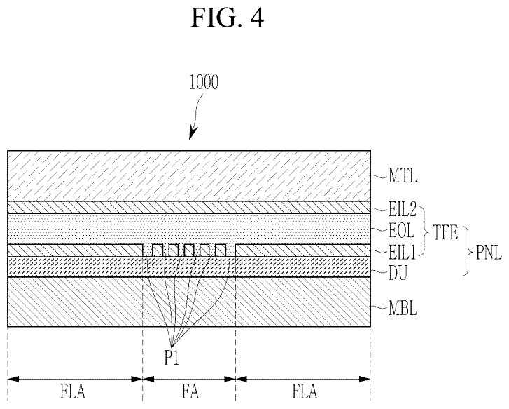

FIG. 4 illustrates a cross-sectional view showing a display device according to some embodiments, including both a folding area and a non-folding area of a display panel PNL.

Referring to FIG. 4, a display device according to some embodiments may include a lower module layer MBL, a display panel PNL located on the lower module layer MBL, and an upper module layer MTL located on the display panel PNL.

The display panel PNL may include a display unit DU and an encapsulation layer TFE located on the display unit DU. The encapsulating layer TFE may include a first inorganic layer EIL1, a second inorganic layer EIL2 located on the first inorganic layer EIL1, and an organic layer EOL located between the first inorganic layer EIL1 and the second inorganic layer EIL2.

The display panel PNL may include a folding area FA and a non-folding area FLA. The display panel PNL may include a first pattern portion P1 located in the folding area FA. The first pattern portion P1 may be included in the first inorganic layer EIL1. The display panel PNL may be subject to folding stress in the folding area FA when folded. When the display panel PNL is folded multiple times, cracks may occur in the first inorganic layer EIL1 due to the folding stress applied to the display panel PNL. To improve this, the first inorganic layer EIL1 arranged to overlap the folding area FA may be patterned to form the first pattern portion P1. The first pattern portion P1 formed by patterning the first inorganic layer EIL1 arranged to overlap the folding area FA may have a concave shape.

Referring to FIG. 4, a material identical to the material of the organic layer EOL may be located on the first pattern portion P1 formed by patterning the first inorganic layer EIL1. The first pattern portion P1 may be filled with the organic layer EOL. Organic materials generally have relatively low modulus compared to inorganic materials, and thus even if folding stress is applied to the display panel PNL, a probability of cracking in the first inorganic layer EIL1 may be relatively low.

Accordingly, a robust display panel PNL that can withstand folding stress applied to the display panel PNL may be provided.

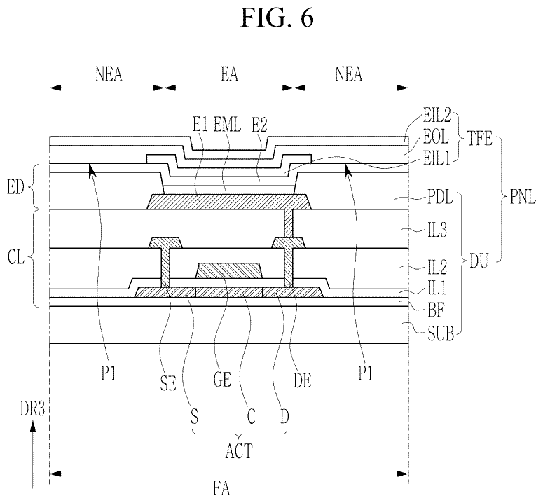

Hereinafter, a specific cross-section of the display panel will be described with reference to FIGS. 5 and 6. FIG. 5 and FIG. 6 each illustrate a cross-sectional view of a display panel according to some embodiments. FIG. 5 and FIG. 6 illustrate a folding area of the display panel.

First, the display unit DU will be described with reference to FIG. 5. The display unit DU may include a substrate SUB, a buffer layer BF, insulating layers IL1, IL2, and IL3, a light emitting element ED, and a partition wall PDL.

The buffer layer BF may be located on the substrate SUB. The substrate SUB may include a flexible material such as plastic that can be bent, folded, or rolled, or may include a rigid substrate.

The buffer layer BF may include silicon nitride (SiNₓ), silicon oxide (SiO₂), silicon oxynitride, or the like. The buffer layer BF may planarize the substrate SUB, and relieve a stress of a semiconductor layer ACT located on the buffer layer BF.

The semiconductor layer ACT may be located on the buffer layer BF. The semiconductor layer ACT may be formed of an oxide semiconductor. The semiconductor layer ACT may include a channel region C, a source region S, and a drain region D. When the semiconductor layer ACT is formed of an oxide semiconductor, a separate protective layer may be added to protect an oxide semiconductor material that is vulnerable to external environments such as high temperature.

A gate insulating layer IL1 may be located on the semiconductor layer ACT. The gate insulating layer IL1 may be a single layer or multiple layers including at least one of silicon nitride (SiNₓ) silicon oxide (SiO₂), or silicon oxynitride.

A gate electrode GE may be located on the gate insulating layer IL1, and may be a single layer or a multilayer in which a metal layer including any one of copper (Cu), a copper alloy, aluminum (Al), an aluminum alloy, molybdenum (Mo), and a molybdenum alloy is stacked.

An interlayer insulating layer IL2 may be located on the gate electrode GE and the gate insulating layer GI. The interlayer insulating layer IL2 may include silicon nitride (SiNₓ) silicon oxide (SiO₂), silicon oxynitride, or the like. The interlayer insulating layer IL2 may have openings that expose each of the source region S and the drain region D.

A source electrode SE and a drain electrode DE may be located on the interlayer insulating layer IL2. The source electrode SE and the drain electrode DE are respectively connected to the source region S and the drain region D of the semiconductor layer ACT through contact holes formed in the first insulating layer IL2.

A protective layer IL3 may be located on the interlayer insulating layer IL2, the source electrode SE, and the drain electrode DE. The protective layer IL3 may cover and planarize the interlayer insulating layer IL2, the source electrode SE, and the drain electrode DE, so that the first electrode E1 may be formed without a step on the protective layer IL3. The protective layer IL3 may be made of an organic material such as a polyacrylate resin or a polyimide resin, or a stacked layer of organic and inorganic materials.

A first electrode E1 may be located on the protective layer IL3. The first electrode E1 may be electrically connected to the drain electrode DE through an opening in the protective layer IL3.

A driving transistor including the gate electrode GE, the oxide semiconductor layer ACT, the source electrode SE, and the drain electrode DE may be connected to each first electrode E1 to supply a driving current to each light emitting element ED. The display device according to the present disclosure may further include: a switching transistor connected to the data line to transfer a data voltage in response to a scan signal; and a compensation transistor connected to the driving transistor to compensate for a threshold voltage of the driving transistor in response to a scan signal, in addition to the driving transistor illustrated in FIG. 5.

The partition wall PDL may be located on the first electrode E1. The partition wall PDL may include an opening defining a light emitting area EA and a non- light emitting area NEA. A light emitting layer EML may be located within the opening. A second electrode E2 may be located on the light emitting layer EML.

Herein, the first electrode E1 may be an anode which is a hole injection electrode, and the second electrode E2 may be a cathode which is an electron injection electrode. However, embodiments according to the present disclosure are not limited thereto, and the first electrode E1 may be a cathode and the second electrode E2 may be an anode depending on a driving method of a display device. Furthermore, a configuration from the first electrode E1 to the second electrode E2 may be referred to as a light emitting element ED.

An encapsulation layer TFE may be located on the second electrode E2. FIG. 5 illustrates a cross-sectional view showing the folding area FA of the display panel, so the encapsulation layer TFE that overlaps the folding area FA is shown. The encapsulating layer TFE may include the first inorganic layer EIL1, the second inorganic layer EIL2 located on the first inorganic layer EIL1, and the organic layer EOL located between the first inorganic layer EIL and the second inorganic layer EIL2.

In a display device according to some embodiments, the first inorganic layer EIL1 may include the first pattern portion P1 located in the non-light emitting area NEA overlapping the folding area FA. When the first inorganic layer EIL1 is patterned to form the first pattern portion P1, various types of patterns may be formed.

According to FIG. 5, the first inorganic layer EIL1 may include the first pattern portion P1 in a portion where one of the non-light emitting areas NEA on opposite sides of the light emitting area EA overlaps the folding area FA. In this case, a material identical to a material of the organic layer EOL may be located in the first pattern portion P1. The organic layer EOL may fill the first pattern portion P1. According to some embodiments, a portion of the organic layer EOL may be in contact with the second electrode E2.

Next, a cross-sectional structure of a display panel according to some embodiments will be described with reference to FIG. 6. Some description of components that are the same as in FIG. 5 described above may be omitted.

Referring to FIG. 6, the first inorganic layer EIL1 may include the first pattern portion P1 in a portion where the non-light emitting areas NEA on opposite sides of the light emitting area EA overlap the folding area FA. In this case, a material identical to a material of the organic layer EOL may be located in the first pattern portion P1. The organic layer EOL may fill the first pattern portion P1. According to some embodiments, a portion of the organic layer EOL may be in contact with the second electrode E2.

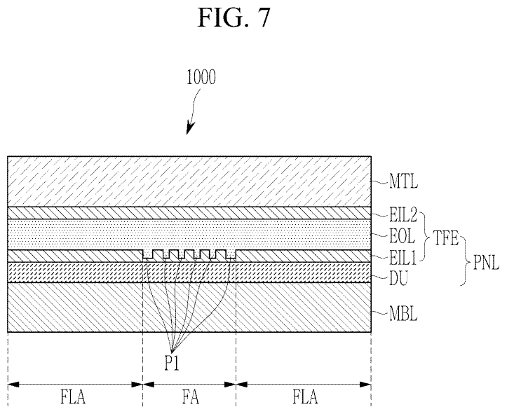

A display device according to some embodiments will now be described with reference to FIG. 7. FIG. 7 illustrates a cross-sectional view showing a display device according to some embodiments, including both a folding area and a non-folding area of a display panel.

Referring to FIG. 7, the display device 1000 according to some embodiments may include the lower module layer MBL, the display panel PNL located on the lower module layer MBL, and the upper module layer MTL located on the display panel PNL.

The display panel PNL may include the display unit DU and the encapsulation layer TFE located on the display unit DU. The encapsulating layer TFE may include the first inorganic layer EIL1, the second inorganic layer EIL2 located on the first inorganic layer EIL1, and the organic layer EOL located between the first inorganic layer EIL and the second inorganic layer EIL2.

The organic layer EIL1 may include the first pattern portion P1. In order to withstand the folding stress applied to the folding area FA of the display panel PNL, the first inorganic layer EIL1 may be patterned to form the first pattern portion P1. The first pattern portion P1 formed by patterning the first inorganic layer EIL1 arranged to overlap the folding area FA may have a concave shape. Referring to FIG. 7, the first pattern portion P1 located in the folding area FA of the display panel may be a region from which at least a portion of the first inorganic layer EIL1 is removed.

A portion of the first inorganic layer EIL1 may include unevenness due to the first pattern portion P1. The organic layer EOL may fill the above-mentioned unevenness while providing a flat upper surface.

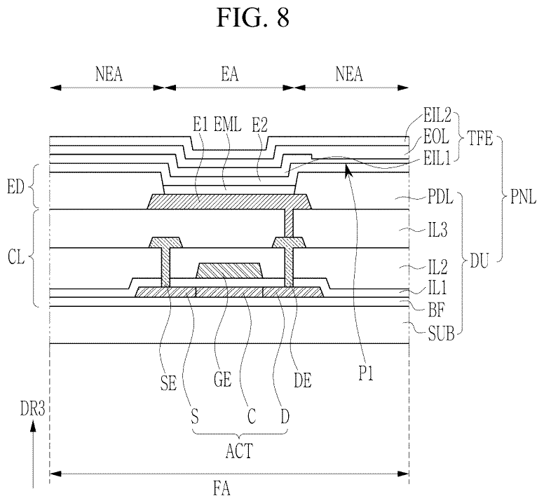

Hereinafter, a pixel located in the folding area will be described with reference to FIG. 8. FIG. 8 illustrates a schematic cross-sectional view of a display panel according to some embodiments. FIG. 8 illustrates the folding area of the display panel.

Referring to FIG. 8, the first pattern portion P1 located in the folding area FA of the display panel PNL may be a region from which at least a portion of the first inorganic layer EIL1 is removed. In this case, the first pattern portion P1 may be located at a portion where one of the non-emitting areas NEA on opposite sides of the light emitting area EA overlaps the folding area FA. However, the present disclosure is not limited thereto, and it may be located at a portion where the non-light emitting areas NEA on opposite sides and the folding area FA overlap the light emitting area EA.

In a display device according to some embodiments, a material identical to a material of the organic layer EOL may be located on the first pattern portion P1 formed by patterning the first inorganic layer EIL1. Organic materials generally have relatively low modulus compared to inorganic materials, and thus even if folding stress is applied to the display panel PNL, a probability of cracking in the inorganic layer may be relatively low. Accordingly, a robust display panel PNL that can withstand folding stress applied to the display panel PNL may be provided.

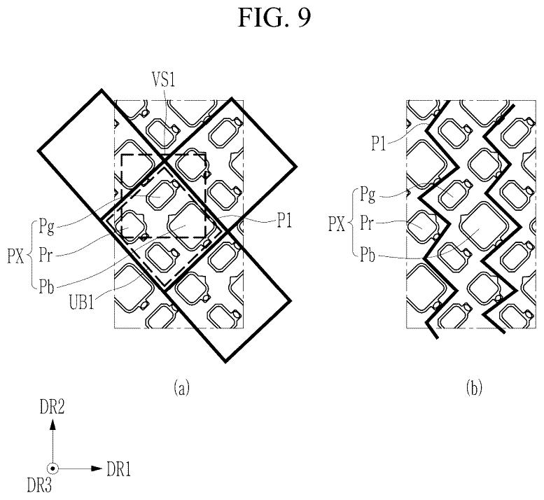

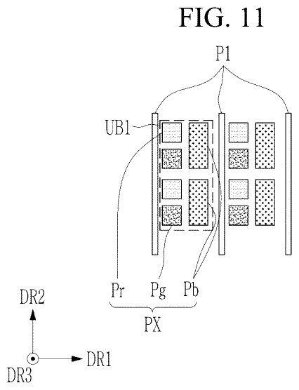

Hereinafter, a display device according to some embodiments will be described with reference to FIG. 9 and FIG. 11. FIG. 9 to FIG. 11 each illustrate a top plan view schematically showing a pixel layout of a portion of a display device according to some embodiments. A pattern structure of the first inorganic layer EIL1 according to some embodiments will be specifically described with reference to FIGS. 9 to 11. Some description of components that are the same as the components described above may be omitted.

First, referring to FIG. 9, a display panel according to some embodiments may have a first unit structure UB1 including a red pixel Pr, a green pixel Pg, and a blue pixel Pb. The first unit structure UB1 may be repeatedly located within the display panel. The first pattern portion P1 may be arranged to surround the first unit structure UB1. The present disclosure is not limited thereto, and the first pattern portion P1 may have a regular arrangement or an irregular arrangement and may be located between the red pixel Pr and the green pixel Pg, between the red pixel Pr and the blue pixel Pb, or between the green pixel Pg and the blue pixel Pb.

As illustrated in FIG. 9, the red pixels Pr, the blue pixels Pb, and the green pixels Pg may have a repeating array structure. The red pixel Pr and the blue pixel Pb may be located at corners of a virtual quadrangle VS1 centered around one green pixel Pg. The red pixel Pr may be located on opposite corners of the virtual quadrangle VS1 with the green pixel Pg therebetween, and the blue pixel Pb may be located on opposite corners of the virtual quadrangle VS1 with the green pixel Pg therebetween in a first direction DR1 of the red pixel Pr. In this case, the virtual quadrangle VS1 may be transformed into various shapes such as a rectangle, a rhombus, a square, etc.

In a different arrangement of subpixels in FIG. 9, the red pixel Pr, the blue pixel Pb, and the green pixel Pg may be arranged in a PENTILE™ structure—e.g., a diamond PENTILE™ structure. However, the present disclosure is not limited thereto.

FIG. 9A illustrates a case in which the first pattern portion P1 is arranged to surround a first unit structure including the red pixel Pr, the green pixel Pg, and the blue pixel Pb in a plan view.

FIG. 9B illustrates a case in which the first pattern portion P1 has an irregular arrangement and is located between the red pixel Pr and the green pixel Pg, or between the green pixel Pg and the blue pixel Pb.

However, the first pattern portion P1 of the present disclosure is not limited thereto, and may have a regular arrangement or an irregular arrangement and may be located anywhere between the red pixel Pr and the green pixel Pg, between the red pixel Pr and the blue pixel Pb, and between the green pixel Pg and the blue pixel Pb.

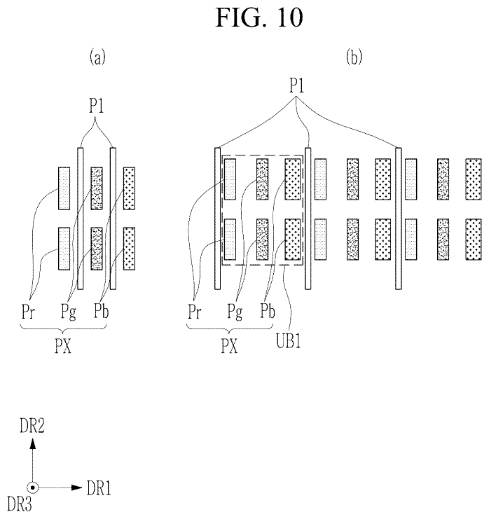

Referring to FIG. 10, a display device according to some embodiments may have red pixels Pr, blue pixels Pb, and green pixels Pg arranged in a stripe structure.

Referring to FIG. 10A, the first pattern portion P1 may have a regular arrangement and may be located between the red pixel Pr and the green pixel Pg, between the red pixel Pr and the blue pixel Pb, and between the green pixel Pg and the blue pixel Pb. The first pattern portion P1 may have a form that extends along the second direction DR2.

Referring to FIG. 10B, the first pattern portion P1 may be located between different first unit structures UB1 including the red pixel Pr, the green pixel Pg, and the blue pixel Pb. According to some embodiments, the first pattern portion P1 may be located between the blue pixel Pb and the red pixel Pr included in different first unit structures.

The first pattern portion P1 may have a form that extends along the second direction DR2.

However, the first pattern portion P1 according to some embodiments is not limited thereto, and may have a regular arrangement or an irregular arrangement and may be located anywhere between the red pixel Pr and the green pixel Pg, between the red pixel Pr and the blue pixel Pb, and between the green pixel Pg and the blue pixel Pb.

Referring to FIG. 11, in a display device according to some embodiments, in one pixel, the red pixel Pr and the green pixel Pg may be arranged such that a width in the first direction DR1 is wider, and the blue pixel Pg may be arranged such that a width in the second direction DR2 is wider. The red pixel Pr and the green pixel Pg may be arranged in a same column, and the blue pixel Pg may be arranged in a column adjacent to the column in which the red pixel Pr and the green pixel Pg are arranged. The column in which the red pixel Pr and the green pixel Pg are arranged and the column in which the blue pixel Pb is arranged may be alternately arranged. In this case, the red pixel Pr, the green pixel Pg, and the blue pixel Pb may be arranged in a same area. The first pattern portion P1 may be located between the different first unit structures UB1 including the red pixel Pr, the green pixel Pg, and the blue pixel Pb.

In some embodiments, the red pixel Pr, the blue pixel Pb, and the green pixels Pg may be arranged in various pixel arrangement structures, such as a mosaic structure, a delta structure, etc.

Meanwhile, each of the red pixel Pr, the blue pixel Pb, and the green pixel Pg may have a quadrangular shape. However, the present disclosure is not limited thereto. In some embodiments, the red pixel Pr, the blue pixel Pb, and the green pixel Pg may have a circular, elliptical, or polygonal shape. The polygonal shape may include rounded vertices.

Sizes (or widths) of the red pixel Pr, the blue pixel Pb, and the green pixel Pg may be provided differently. For example, the size (or width) of the green pixel Pg may be made smaller than that of the red pixel Pr and the blue pixel Pb. The size (or width) of the blue pixel Pb may be made larger than the size (or width) of the red pixel Pr. According to some embodiments, various modifications are possible, such as the sizes of the red pixel Pr, the blue pixel Pb, and the green pixel Pg being substantially the same.

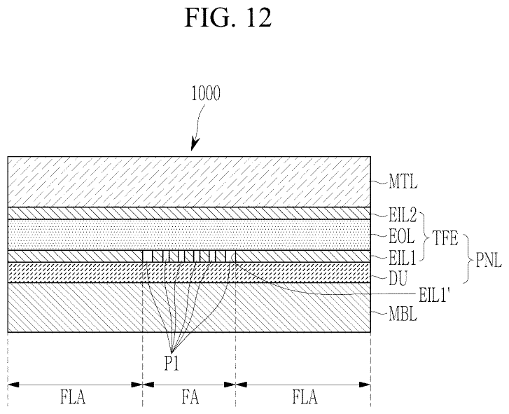

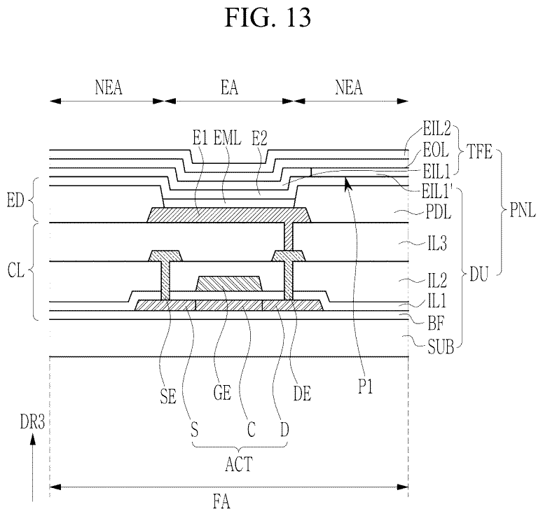

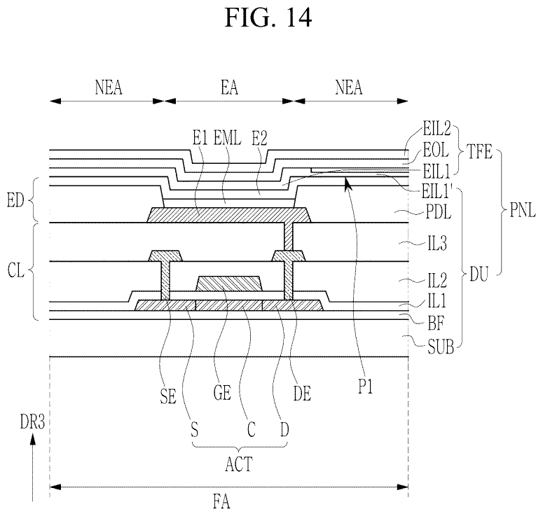

Hereinafter, a display device according to some embodiments will be described with reference to FIG. 12 and FIG. 14. FIG. 12 illustrates a cross-sectional view showing a display device according to some embodiments, including both a folding area and a non-folding area of a display panel PNL. FIGS. 13 and 14 illustrate specific cross-sectional views of a display panel when a first material is arranged in a first pattern portion. Duplicate descriptions may be omitted.

First, referring to FIG. 12, a display device according to some embodiments may include a lower module layer MBL, a display panel PNL located on the lower module layer MBL, and an upper module layer MTL located on the display panel PNL.

The display panel PNL may include a display unit DU and an encapsulation layer TFE located on the display unit DU. The encapsulating layer TFE may include the first inorganic layer EIL1, a second inorganic layer EIL2 located on the first inorganic layer EIL1, and the organic layer EOL located between the first inorganic layer EIL and the second inorganic layer EIL2.

The display panel PNL may be subject to folding stress in the folding area FA during folding. When the display panel PNL is folded multiple times, cracks may occur in the first inorganic layer EIL1 due to the folding stress applied to the display panel PNL. To improve this, the first inorganic layer EIL1 arranged to overlap the folding area FA may be patterned to form the first pattern portion P1. The first pattern portion P1 formed by patterning the first inorganic layer EIL1 arranged to overlap the folding area FA may have a concave shape. The first pattern portion P1 located in the folding area of the display panel may have a first material EIL1′ having a lower modulus than the first inorganic layer EIL1.

In the first pattern portion P1, the first material EIL1′ may be filled under process conditions different from those of the non-folding area FLA to complement the characteristics of the encapsulating layer TFE. The first material EIL1′ may include at least one of an organic material or an inorganic material. The first material EIL1′ may be a low-density layer. According to some embodiments, the low-density layer may be formed by varying process conditions in the non-folding area FLA. This may be formed by changing a gas flow and a process power source (RF power) in a chemical vapor deposition (CVD) process. The low-density layer may be a single-layer or multilayer SiOxNy layer. The first material EIL1′ may include a styrene-based thermoplastic elastomer.

The first material EIL1′ may be partially filled by different methods. In this case, an initiated chemical vapor deposition (iCVD) process or a plasma-enhanced atomic layer deposition (PEALD) process may be used.

Referring to FIG. 1, the first pattern portion P1 located in the folding area of the display panel may have the first material EIL1′ having a lower modulus than the first inorganic layer EIL1. In this case, the first pattern portion P1 may be located at a portion in which one of the non-emitting areas NEA on opposite sides of the light emitting area EA overlaps the folding area FA. However, the present disclosure is not limited thereto, and it may be located at a portion in which the non-light emitting areas NEA on opposite sides and the folding area FA overlap the light emitting area EA.

Referring to FIG. 14, the first pattern portion P1 located in the folding area of the display panel may be a region from which at least a portion of the first inorganic layer is removed. In this case, the first material EIL1′ having a modulus smaller than that of the first inorganic layer may be located in the first pattern portion P1. The first pattern portion P1 may be located at a portion in which one of the non-emitting areas NEA on opposite sides of the light emitting area EA overlaps the folding area FA. However, the present disclosure is not limited thereto, and it may be located at a portion in which the non-light emitting areas NEA on opposite sides and the folding area FA overlap the light emitting area EA.

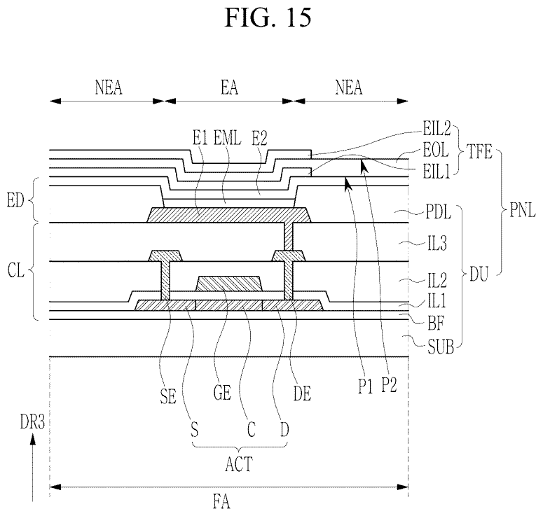

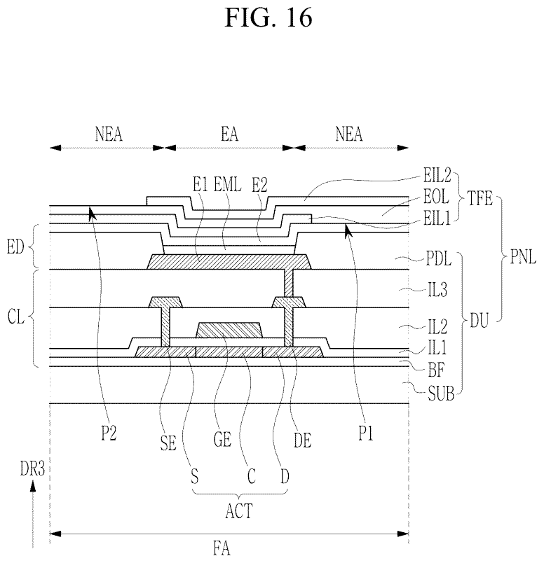

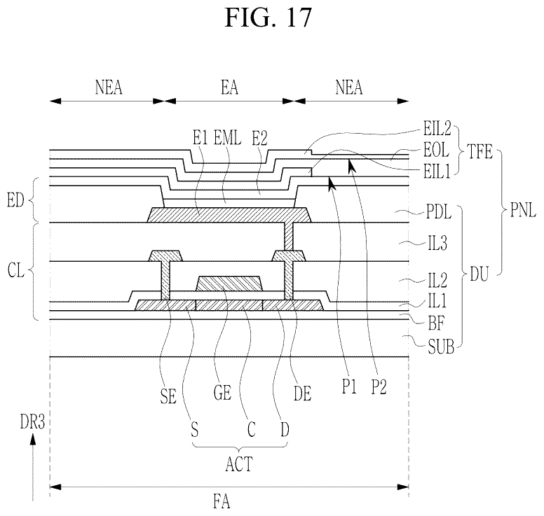

Hereinafter, a cross-sectional view showing a display panel having a second pattern portion by patterning a second inorganic layer will be described with reference to FIGS. 15 to 17. FIG. 15 illustrates a cross-sectional view for a case in which a first pattern portion obtaining by patterning a first inorganic layer and a second pattern portion obtained by patterning a second inorganic layer are arranged to overlap each other. FIG. 16 illustrates a cross-sectional view for a case in which the first pattern portion and the second pattern portion are spaced apart from each other, and FIG. 17 illustrates a view for a case in which the second pattern portion P2 is a region in which at least a portion of the second inorganic layer EIL2 is removed.

FIG. 15 to FIG. 17 each illustrate a cross-sectional view showing the folding area FA of the display panel, showing the encapsulation layer TFE that overlaps the folding area FA. The encapsulating layer TFE may include the first inorganic layer EIL1, the second inorganic layer EIL2 located on the first inorganic layer EIL1, and the organic layer EOL located between the first inorganic layer EIL and the second inorganic layer EIL2.

First, referring to FIG. 15, the first inorganic layer EIL1 may include the first pattern portion P1 located in the non-light emitting area NEA overlapping the folding area FA. When the first inorganic layer EIL1 is patterned to form the first pattern portion P1, various types of patterns may be formed. The first pattern portion P1 may have a shape of a recess.

The second inorganic layer EIL2 may be located on the functional layer EOL. In a display device according to some embodiments, the second inorganic layer EIL2 may include the second pattern portion P2 located in the non-light emitting area NEA overlapping the folding area FA. When the second inorganic layer EIL2 is patterned to form the second pattern portion P2, various types of patterns may be formed. The second pattern portion P2 may have a shape of a recess.

According to FIG. 15, at least one of the first inorganic layer EIL1 or the second inorganic layer EIL2 may include a recess portion located in a non-light emitting area NEA that overlaps the folding area FA. The first pattern portion P1 having a concave shape and located on the first inorganic layer EIL1 and the second pattern portion P2 having a concave shape and located on the second inorganic layer EIL2 may be arranged to overlap each other.

The first inorganic layer EIL1 may include the first pattern portion P1 located in the non-light emitting area NEA overlapping the folding area FA. In a display device according to some embodiments, the second inorganic layer EIL2 may further comprise the second pattern portion P2 located in the non-light emitting area NEA overlapping the folding area FA. In this case, the first pattern portion P1 and the second pattern portion P2 may be arranged to overlap each other.

Referring to FIG. 15, at least one of the first inorganic layer EIL1 or the second inorganic layer EIL2 may include a recess portion located in a non-light emitting area NEA that overlaps the folding area FA. The concave portion located in the first inorganic layer EIL1 and the concave portion located in the second inorganic layer EIL2 may be spaced apart from each other.

The first inorganic layer EIL1 may include the first pattern portion P1 located in the non-light emitting area NEA overlapping the folding area FA. In a display device according to some embodiments, the second inorganic layer EIL2 may include the second pattern portion P2 located in the non-light emitting area NEA overlapping the folding area FA. In this case, the first pattern portion P1 and the second pattern portion P2 may be spaced apart from each other.

According to FIG. 17, at least one of the first inorganic layer EIL1 or the second inorganic layer EIL2 may include a recess portion located in a non-light emitting area NEA that overlaps the folding area FA. In this case, the concave portion may be an area in which the first inorganic layer EIL1 and the second inorganic layer EIL2 are at least partially removed.

The first inorganic layer EIL1 may include the first pattern portion P1 located in the non-light emitting area NEA overlapping the folding area FA. In a display device according to some embodiments, the second inorganic layer EIL2 may include the second pattern portion P2 located in the non-light emitting area NEA overlapping the folding area FA. The second pattern portion P2 may be a region from which at least a portion of the second inorganic layer EIL2 is removed. In this case, the first pattern portion P1 and the second pattern portion P2 may be arranged to overlap or to be spaced apart from each other.

Although the present specification illustrates embodiments in which the second pattern portion P2 has at least a portion of the second inorganic layer EIL2 removed, the present disclosure is not limited thereto, and at least one of the first pattern portion P1 or the second pattern portion P2 may have a form in which a portion of the inorganic layer is removed.

A display device according to some embodiments may provide a display panel that is robust against folding stress by patterning an inorganic layer of an encapsulating layer overlapping a folding area so that a material capable of withstanding the folding stress may be located in the pattern portion. The first inorganic layer of the encapsulation layer may be patterned to have a first pattern portion, and the second inorganic layer may also be patterned to have a second pattern portion. The pattern portion may be an area from which at least a portion of the inorganic layer has been removed. The pattern portion may be located in a portion that overlaps the non-light emitting area so as not to be visible during light emission. The pattern portion may include a material having a lower modulus than that of the inorganic layer, which may include at least one of an organic material or an inorganic material.

In this way, by patterning the inorganic layer and positioning a material resistant to folding stress on the pattern portion, it may be possible to prevent or reduce cracks in the inorganic layer that may occur during multiple foldings and provide a robust display panel that can withstand folding stress well.

A display device according to some embodiments may be applied to various electronic devices. An electronic device according to some embodiments may include the display device, and may further include modules or devices having additional functions other than the display device.

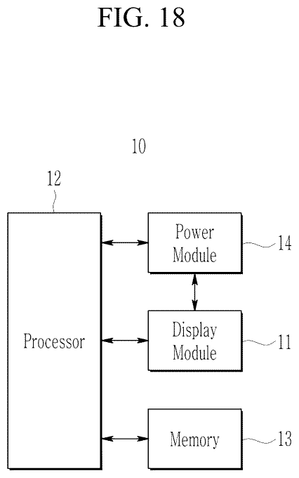

FIG. 18 is a block diagram of an electronic device according to some embodiments. Referring to FIG. 18, the electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

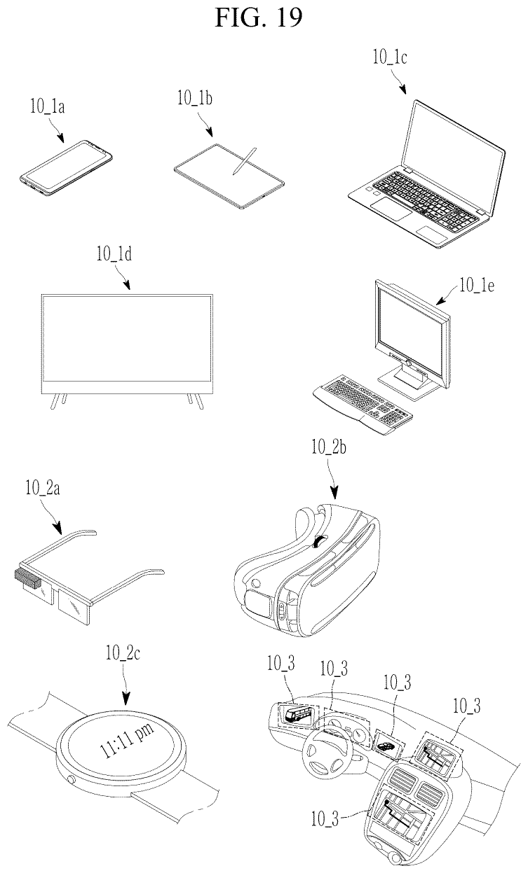

FIG. 19 shows schematic diagrams of electronic devices according to various embodiments.

Referring to FIG. 19, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While aspects of some embodiments of the present disclosure have been described in connection with what is presently considered to be practical embodiments, it is to be understood that embodiments according to the present disclosure are not limited to the disclosed embodiments, but, on the contrary, is intended to cover various modifications and equivalent arrangements included within the spirit and scope of the appended claims, and their equivalents.

### DESCRIPTION OF SOME OF THE REFERENCE SYMBOLS

1000: display device
100: cover window
MTL: upper module layer
PNL: display panel
MBL: lower module layer
DU: display unit
TFE: encapsulation layer
EIL1: first inorganic layer
EOL: organic layer
EIL2: second inorganic layer
FA: folding area
FLA: non-folding area
EA: light emitting area
NEA: non-light emitting area
P1: first pattern portion
P2: second pattern portion

What is claimed is:

1. A display device comprising:
a display panel comprising:
a display unit; and
an encapsulation layer on the display unit,
wherein the display panel includes a folding area and a non-folding area,
the display unit comprising:
a substrate;
a transistor on the substrate;
a first electrode on the transistor;
a partition wall on the first electrode and including an opening defining a light emitting area and a non-light emitting area; and
a light emitting layer within the opening,
the encapsulation layer comprising:
a first inorganic layer;
a second inorganic layer on the first inorganic layer; and
an organic layer between the first inorganic layer and the second inorganic layer, and
the first inorganic layer includes a first pattern portion in the non-light emitting area overlapping the folding area.

2. The display device of claim 1, wherein a material that is identical to a material of the organic layer is on the first pattern portion.

3. The display device of claim 1, wherein a first material having a lower modulus than that of the first inorganic layer is on the first pattern portion.

4. The display device of claim 3, wherein the first material includes at least one of an organic material or an inorganic material.

5. The display device of claim 3, wherein the first material includes a styrene-based thermoplastic elastomer.

6. The display device of claim 1, wherein the first pattern portion is a region from which at least a portion of the first inorganic layer has been removed.

7. The display device of claim 1, wherein the second inorganic layer further comprises a second pattern portion in the non-light emitting area overlapping the folding area.

8. The display device of claim 7, wherein the second pattern portion is a region from which at least a portion of the second inorganic layer has been removed.

9. The display device of claim 7, wherein the first pattern portion and the second pattern portion overlap each other.

10. The display device of claim 7, wherein the first pattern portion and the second pattern portion are spaced apart from each other.

11. The display device of claim 1, wherein
the display unit has a first unit structure that comprises a red pixel, a green pixel, and a blue pixel, and the first unit structure is arranged repeatedly, and
the first pattern portion surrounds the first unit structure.

12. The display device of claim 11, wherein
the red pixel and the blue pixel are at corners of a virtual quadrangle with the green pixel as a center point,
the red pixel is at an opposite corner with the green pixel therebetween, and
the blue pixel is at an opposite corner of the red pixel in a first direction, with the green pixel therebetween.

13. A display device comprising:
a display panel comprising:
a display unit; and
an encapsulation layer on the display unit,
wherein the display panel includes a folding area and a non-folding area,
the display unit includes:
a substrate;
a transistor on the substrate;
a first electrode on the transistor;
a partition wall on the first electrode and including an opening defining a light emitting area and a non-light emitting area;
a light emitting layer within the opening; and
a second electrode on the light emitting layer,
the encapsulation layer comprising:
a first organic layer on the second electrode;
a second inorganic layer on the first inorganic layer; and
an organic layer between the first inorganic layer and the second inorganic layer, and
at least one of the first inorganic layer or the second inorganic layer includes a recess portion in the non-light emitting area that overlaps the folding area.

14. The display device of claim 13, wherein a material that is identical to a material of the organic layer is in the recess portion.

15. The display device of claim 13, wherein a first material having a lower modulus than that of the first inorganic layer is in the recess portion.

16. The display device of claim 15, wherein the first material includes at least one of an organic material or an inorganic material.

17. The display device of claim 13, wherein the recess portion is an area where the first inorganic layer and the second inorganic layer have been at least partially removed.

18. The display device of claim 13, wherein the recess portion in the first inorganic layer and the recess portion in the second inorganic layer overlap each other.

19. The display device of claim 13, wherein the recess portion in the first inorganic layer and the recess portion in the second inorganic layer are spaced apart from each other.

20. An electronic device comprising:
a memory;
a processor executing an application stored in the memory; and
a display device comprising a display module configured to output video information provided by the application, wherein
the display device comprising:
a display panel comprising:
a display unit; and
an encapsulation layer on the display unit,
wherein the display panel includes a folding area and a non-folding area,
the display unit comprising:
a substrate;
a transistor on the substrate;
a first electrode on the transistor;
a partition wall on the first electrode and including an opening defining a light emitting area and a non-light emitting area; and
a light emitting layer within the opening,
the encapsulation layer comprising:
a first inorganic layer;
a second inorganic layer on the first inorganic layer; and
an organic layer between the first inorganic layer and the second inorganic layer, and
the first inorganic layer includes a first pattern portion in the non-light emitting area overlapping the folding area.
